(19) United States
(12) Patent Application Publication
(10) Pub. No.: US 2005/0023691 A1
(43) Pub. Date: Feb. 3, 2005

(54) Semiconductor device and manufacturing method thereof

(76) Inventors: Kei Watanabe, Oita-shi (JP); Takahito Nagamatsu, Oita-shi (JP)

Correspondence Address: Finnegan, Henderson, Farabow,;Garrett & Dunner, L.L.P., 1300 I Street, N.W., Washington, DC, 20005-3315, US

(21) Appl. No.: 10/697,438

(22) Filed: Oct. 31, 2003

(30) Foreign Application Priority Data
Jul. 31, 2003 (JP) 2003-204578

(51) Int. Cl. H01L 23/48

(52) U.S. Cl. 257/758

(57) ABSTRACT

A semiconductor device includes a metal wiring provided on a semiconductor substrate. The device further includes an anti-metal diffusion film formed on the metal wiring, a buffer layer which is formed on the anti-metal diffusion film and includes at least a silicon-methyl radical bond and a silicon-oxygen bond, and a low-dielectric constant film layer which is formed on the buffer layer and includes at least the silicon-methyl radical bond and the silicon-oxygen bond, wherein the silicon-methyl radical bonding density of the buffer layer is less than the silicon-methyl radical bonding density of the low-dielectric constant film layer.

### CROSS-REFERENCE TO RELATED APPLICATIONS

This application is based upon and claims the benefit of priority from the prior Japanese Patent Application No. 2003-204578, filed Jul. 31, 2003, the entire contents of which are incorporated herein by reference.

### BACKGROUND OF THE INVENTION

1. Field of the Invention

The present invention relates to a semiconductor device and a manufacturing method thereof. More particularly, the present invention relates to formation of a low-dielectric constant silicon oxide film by a plasma chemical vapor deposition (CVD) method on a semiconductor substrate in process.

2. Description of the Related Art

Conventionally, in a semiconductor device, a silicon oxide (SiO₂) film is often used as an insulating film utilized to electrically isolate between wirings in a device. This SiO₂ film is mainly formed by a low pressure or atmospheric pressure CVD method using such as SiH₄ or tetraethoxysilane (TEOS) as a source gas. In particular, since the film can be formed by at a low temperature of approximately 400° C., an SiO₂ film formed by the plasma CVD method using a TEOS gas and an O₂ gas is recently in heavy usage. Usually, in the CVD method, a high-purity gas is often used as a reaction source gas. Therefore, as compared with any other thin-film formation method, a high-quality film can be obtained.

Further, in this type of semiconductor device, a delay in signal transmission becomes one of issues recently. Signal transmission is delayed because a space between wirings is narrowed as the device becomes finer and a capacitance between wirings is thereby increased. A problem of this signal transmission delay can be a factor which obstructs an improvement in performance of a semiconductor device. In order to solve this problem, a dielectric constant of an insulating film between wirings must be lowered as much as possible.

Likewise, in regard to wiring materials, copper (Cu) having a low specific resistance which is approximately 1/2 of that of conventionally used aluminium (Al) has been examined actively. However, a reactive ion etching (RIE) process which has been adopted as an Al wiring etching technique for a long time cannot be applied to etching of a Cu wiring. That is because a Cu compound having a sufficiently high vapor pressure does not exist. Therefore, a Damascene method is dedicatedly used for formation of a Cu wiring.

On the other hand, as an insulating film which can lower a dielectric constant, development of a methyl radical-containing silicon oxide film (Metylsilsesquioxane; which will be referred to as an MSQ film hereinafter) has advanced (see, e.g., Jpn. Pat. Appln. KOKAI Publication No. 2002-93805). A parallel plate type plasma CVD method or a spin on dielectric (SOD) method is employed for formation of this MSQ film. The MSQ film generates voids in a molecular structure since many Si—CH₃ bonds exist in the film. It is explained that a porous structure is thereby created and a dielectric constant is lowered. As an Si material used to form the MSQ film by the plasma CVD method, there has been reported, e.g., SiH(CH₃)₃ or Si(CH₃)₄.

However, the MSQ film has problems due to the porous structure such as degradation in a mechanical strength or degradation in an interface adhesion with another type of film. That is, as reported before, when thermal stresses are applied during wafer processes, cracking or film peeling readily occurs in the MSQ film. It also occurs when a mechanical stress which a device receives in a packaging process such as a bonding process or a dicing process, typically or a thermal cycle stress in a temperature range assumed in an actual operation is applied. As described above, adoption of the MSQ film can improve the performance of the semiconductor device but lead to a degradation in reliability.

### BRIEF SUMMARY OF THE INVENTION

According to a first aspect of the present invention, there is provided a semiconductor device comprising: a metal wiring provided on a semiconductor substrate; an anti-metal diffusion film formed on the metal wiring; a buffer layer which is formed on the anti-metal diffusion film and includes at least a silicon-methyl radical bond and a silicon-oxygen bond; and a low-dielectric constant film layer which is formed on the buffer layer and includes at least the silicon-methyl radical bond and the silicon-oxygen bond, wherein the silicon-methyl radical bonding density of the buffer layer is less than the silicon-methyl radical bonding density of the low-dielectric constant film layer.

According to a second aspect of the present invention, there is provided a manufacturing method of a semiconductor device comprising: forming an anti-metal diffusion film on a metal wiring provided on a semiconductor substrate; and forming a buffer layer including at least a silicon-methyl radical bond and a silicon-oxygen bond on the anti-metal diffusion film and forming a low-dielectric constant film layer including at least the silicon-methyl radical bond and the silicon-oxygen bond on the buffer layer, wherein the buffer layer is formed in such a manner that its silicon-methyl radical bonding density is less than the silicon-methyl radical bonding density of the low-dielectric constant film layer.

### BRIEF DESCRIPTION OF THE SEVERAL VIEWS OF THE DRAWING

FIG. 1 is a cross-sectional view showing a basic structure of a semiconductor device according to an embodiment of the present invention;

FIG. 2 is a view showing a structural example of a plasma CVD apparatus used in manufacturing the semiconductor device depicted in FIG. 1;

FIG. 3 is a process cross-sectional view illustrating a manufacturing method of the semiconductor device depicted in FIG. 1;

FIG. 4 is a process cross-sectional view illustrating a manufacturing method of the semiconductor device depicted in FIG. 1;

FIG. 5 is a process cross-sectional view illustrating a manufacturing method of the semiconductor device depicted in FIG. 1;

FIG. 6 is a process cross-sectional view illustrating a manufacturing method of the semiconductor device depicted in FIG. 1;

FIG. 7 is a process cross-sectional view illustrating a manufacturing method of the semiconductor device depicted in FIG. 1; and

FIG. 8 is a view showing a relationship between an FT-IR peak height ratio and an interface adhesion strength of a buffer layer and a low-dielectric constant film layer.

### DETAILED DESCRIPTION OF THE INVENTION

An embodiment according to the present invention will be described with reference to the accompanying drawings hereinafter.

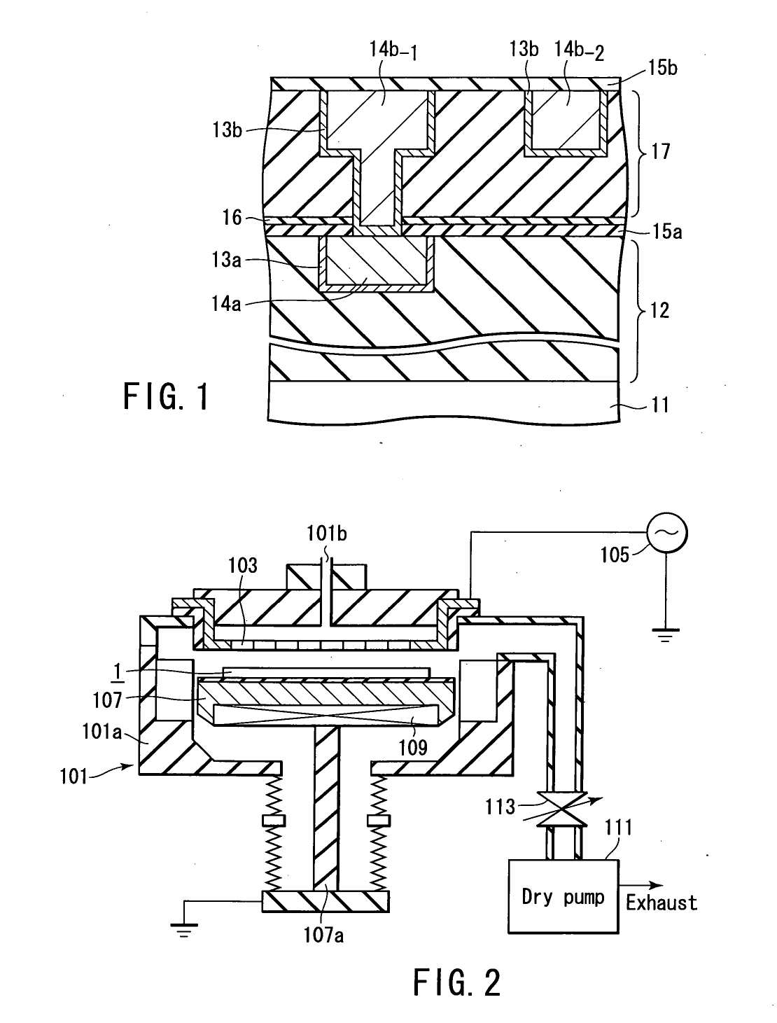

FIG. 1 shows a basic structure of a semiconductor device according to an embodiment of the present invention. It is to be noted that a semiconductor device having a multilayer wiring structure will be described taking a case that a double layered wiring is provided as an example.

As shown in FIG. 1, for example, an underlying insulating film 12 is provided on a silicon (which will be abbreviated as an Si hereinafter) substrate 11 having devices formed therein. A first copper (which will be abbreviated as a Cu hereinafter) wiring 14a as a metal wiring of the underlying layer (first layer) is embedded in a part of a surface area of the underlying insulating film 12 accompanying a first barrier metal film 13a. Further, a first methyl radical-containing silicon nitride film (SiCN film) 15a served as an anti-metal diffusion film is provided on the underlying insulating film 12 including the first Cu wiring 14a and the first barrier metal film 13a. A buffer layer (a first methyl radical-containing silicon oxide film: MSQ film) 16 containing at least a silicon-methyl radical (Si—CH₃) bond and a silicon-oxygen bond is formed on the first methyl radical-containing silicon nitride film 15a. The buffer layer 16 has a film thickness of approximately 10 nm (desirably not more than 30 nm). Furthermore, a low-dielectric constant film layer containing at least a silicon-methyl radical bond and a silicon-oxygen bond (second methyl radical-containing silicon oxide film) 17 is provided on the buffer layer 16. The low-dielectric constant film layer 17 has a relative dielectric constant ∈ of not more than 3.1 (preferably ∈≦3).

Here, the buffer layer 16 has its silicon-methyl radical bonding density which is less than a silicon-methyl radical bonding density of the low-dielectric constant film layer 17. In this embodiment, in the buffer layer 16, a ratio of the silicon-methyl radical bonding density to the silicon-oxygen bonding density (which will be referred to as an FT-IR peak height ratio hereinafter) is not more than 22%. On the contrary, the FT-IR peak height ratio of the low-dielectric constant film layer 17 is not less than 25%.

Second Cu wirings 14b_{—1} and 14b_{—2} serve as metal wirings of the upper layer (second layer) are embedded in a part of a surface area of the low-dielectric constant film layer 17 accompanying the second barrier metal layer 13b. Of the second Cu wirings 14b_{—1} and 14b_{—2}, for example, one second Cu wiring 14b_{—1} is electrically connected to the first Cu wiring 14a through the first buffer layer 16 and the first methyl radical-containing silicon nitride film 15a. Moreover, a second methyl radical-containing silicon nitride film (SiCN film) 15b as an anti-metal diffusion film is provided on the low-dielectric constant film layer 17 including surface area of the second Cu wirings 14b_{—1} and 14b_{—2} and the second barrier metal film 13. In this manner, the semiconductor device having a multilayer wiring structure with at least a double layered wiring is formed.

As described above, the silicon-methyl radical bonding density in the buffer layer 16 is set to be less than the silicon-methyl radical bonding density in the low-dielectric constant film layer 17. As a result, it is possible to suppress a degradation in a mechanical strength or an adhesion at an interface between the first methyl radical-containing silicon nitride film 15a and the buffer layer 16 and an interface between the buffer layer 16 and the low-dielectric constant film layer 17. That is, in order to improve the adhesion of the low-dielectric constant film layer 17, the buffer layer 16 whose silicon-methyl radical bonding density is smaller than that of the low-dielectric constant film layer 17 is provided between the first methyl radical-containing silicon nitride film 15a and the low-dielectric constant film layer 17. As a result, in the semiconductor device having the low-dielectric constant film layer 17 formed using an organic silicon compound containing a methyl radical as a raw material on the first methyl radical-containing silicon nitride film 15a, a capacitance between the wirings can be reduced without causing film cracks or film peeling. Therefore, the performance of the semiconductor device can be improved, and a degradation in the reliability can be prevented.

FIG. 2 shows an example of a plasma CVD apparatus which is used in manufacture of the above-described semiconductor device. Here, a description will be given taking a parallel plate type plasma CVD apparatus using a radio-frequency power supply of 13.56 MHz as an example. This parallel plate type plasma CVD apparatus includes a reaction chamber 101. The reaction chamber 101 is constituted by including a metal chamber portion 101a and a source gas inlet portion 101b. A source gas (e.g., SiH(CH₃)₃, O₂, He) whose flow rate is controlled by a non-illustrated massflow controller (MFC) is supplied into the metal chamber portion 101a. The source gas is led into the metal chamber portion 101a from the source gas inlet portion 101b, and is evenly dispersed by a gas dispersion plate 103 at that time.

The gas dispersion plate 103 also functions as an upper radio frequency (RF) electrode, and is grounded through an RF power supply 105. In a capacitive coupled mode a capacitive coupled plasma is induced in a space of the metal chamber portion 101a by applying a power form the RF power supply 105 to the RF electrode.

On the other hand, a substrate ground electrode 107 as a susceptor can hold the Si substrate in an Si wafer (semiconductor substrate in process) 1 state. Additionally, the substrate ground electrode 107 is supported by a lift mechanism 107a so as to be capable of moving up and down, and constituted so as to be capable of controlling a distance between the gas dispersion plate 103 and the Si wafer 1. Further, the substrate ground electrode 107 includes a heater 109, and can control a temperature of the Si wafer (e.g., heating up to approximately 450°).

A dry pump 111 is connected to the metal chamber portion 101a. This dry pump 111 can form a vacuum in the metal chamber portion 101a. Furthermore, a pressure in the metal chamber portion 101a can be controlled by a throttle valve 113.

A description will now be given as to a method of manufacturing the semiconductor device having the structure depicted in FIG. 1 by using such a parallel plate type plasma CVD apparatus. First, the Si wafer 1 is prepared. In the Si wafer 1, the first Cu wiring 14a is formed on a surface of the underlying insulating film 12 on each Si substrate 11 accompanying the first barrier metal film 13a, and the first methyl radical-containing silicon nitride film 15a is formed on the entire surface.

The Si wafer 1 is inserted into the metal chamber portion 101a of the parallel plate type plasma CVD apparatus depicted in FIG. 2, and held on the substrate ground electrode 107. At that time, a distance between the Si wafer 1 and the gas dispersion plate 103 is controlled by the lift mechanism 107a. Further, a temperature of the Si wafer 1 is controlled by the heater 109. Thereafter, the source gas is led from the source gas inlet portion 101b. The source gas is supplied into the metal chamber portion 101a through the gas dispersion plate 103. The source gas is led under the condition of 500 sccm of SiH(CH₃)₃, 250 sccm of O₂ and 100 sccm of He for example.

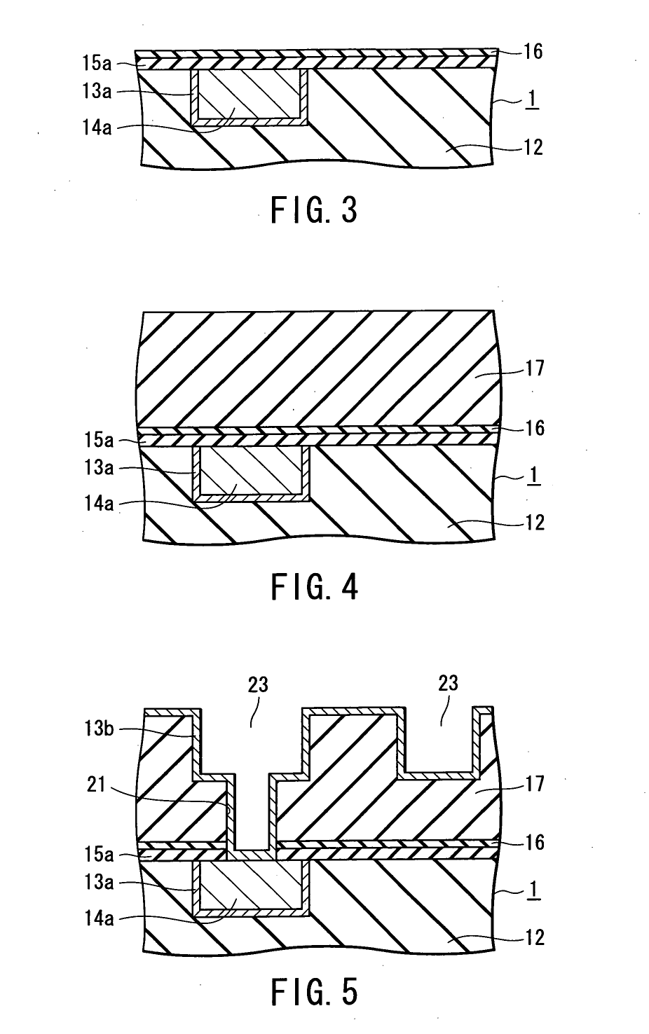

On the other hand, the dry pump 111 evacuates the metal chamber portion 101a, and a pressure in the metal chamber portion 101a is controlled to approximately 2 torr (preferably not more than 3 torr) by the throttle valve 113. Furthermore, when the pressure and the gas flow rate are stabilized, the power of approximately 1000 W is applied from the RF power supply 105 to the gas dispersion plate (RF electrode) 105. As a result, the RF power density during the film formation is controlled to be not less than 2 W/cm³, and a film of the buffer layer 16 is formed for a predetermined period. In this way, for example, as shown in FIG. 3, the buffer layer 16 having a film thickness of approximately 10 nm whose FT-IR peak height ratio is not more than 22% is formed on the first methyl radical-containing silicon nitride film 15a.

After forming the buffer layer 16, the source gas is led into the metal chamber portion 101a under the condition of, e.g., 500 sccm of SiH(CH₃)₃, 250 sccm of O₂ and 100 sccm of He. Moreover, a pressure in the metal chamber portion 101a is controlled to approximately 5 torr by the throttle valve 113. Additionally, when the pressure and the gas flow rate are stabilized, the power of approximately 750 W is applied from the RF power supply 105 to the gas dispersion plate (RF electrode) 103. As a result, the RF power density during the film formation is controlled to be not less than 1.5 W/cm², and a film of the low-dielectric constant film layer 17 is formed for a predetermined period. As a result, for example, as shown in FIG. 4, the low-dielectric constant film layer 17 having a film thickness of approximately 400 nm to 600 nm whose FT-IR peak height ratio is not less than 25% is formed on the buffer layer 16.

It is to be noted that formation of the buffer layer 16 and the low-dielectric constant film layer 17 can be formed by continuously forming the films in a same step without turning off the RF power supply 105, as well as by discontinuously forming the films by turning on the RF power supply 105 again, i.e., dividing into a first step of forming the buffer layer 16 and a second step of forming the low-dielectric constant film layer 17. Additionally, a silicon oxide film having a film thickness of approximately 200 nm as a passivation film may be deposited on the low-dielectric constant film layer 17 by the plasma SVD method.

After forming the low-dielectric constant film layer 17, formation of the second Cu wirings 14b_{—1} and 14b_{—2} is performed. In this embodiment, first, a contact plug used to make an electrical contact with the first Cu wiring 14a is formed. That is, a resist (not shown) having a desired pattern transferred thereto by a lithography process is formed on the low-dielectric constant film layer 17. With this resist being used as a mask, the low-dielectric constant film layer 17 and the buffer layer 16 are selectively etched by reactive ion etching and the like, and a part of a through hole 21 used to embed the contact plug which is connected to the first Cu wiring 14a is formed. Subsequently, another resist (not shown) having a desired pattern transferred thereto by the lithography process is reformed on the low-dielectric constant film layer 17 in the similar manner. Further, with that resist being used as a mask, the low-dielectric constant film layer 17 is selectively etched by the reactive ion etching and the like, thus wiring grooves 23 for the second Cu wirings 14b_{—1} and 14b_{—2} are respectively formed. Then, the first methyl radical-containing silicon nitride film 15a is selectively removed by reactive ion etching and the like, and the through hole 21 used to embed the contact plug which is connected to the first Cu wiring 14a is formed. At that time, the through hole 21 is connected with at least one wiring groove 23. Thereafter, the second barrier metal film 13b is deposited in the through hole 21 and the wiring grooves 23 by a sputtering method or an metal organic CVD (MOCVD) method (see FIG. 5).

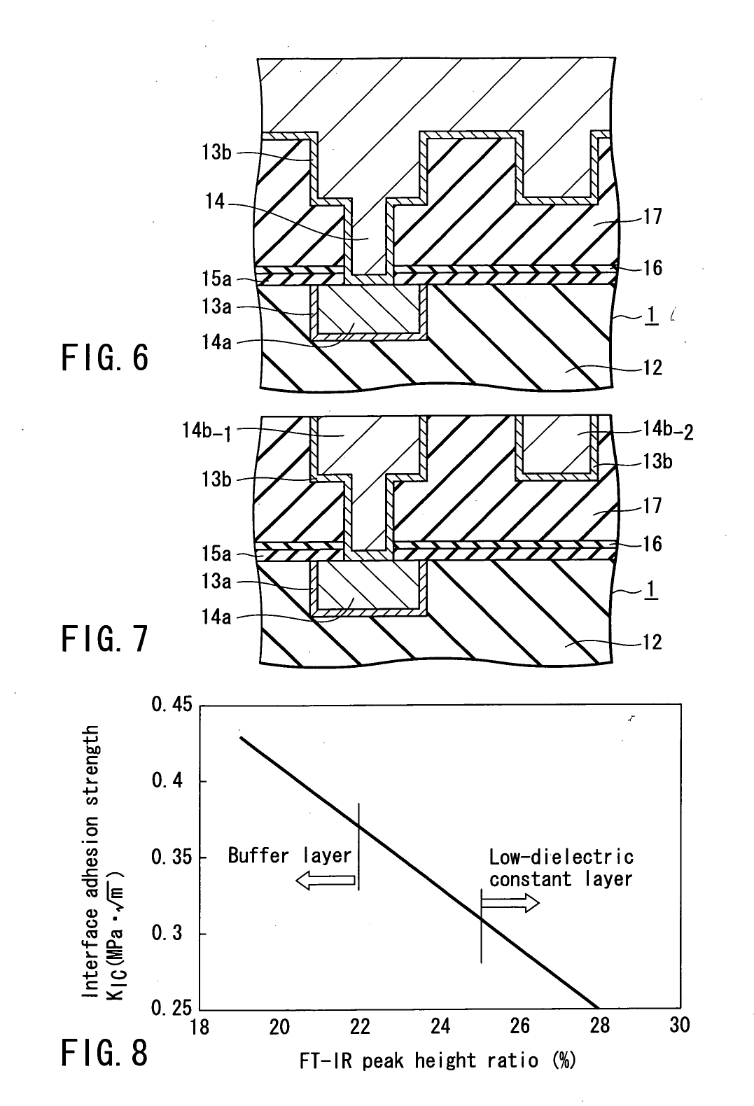

Subsequently, for example, as shown in FIG. 6, the Cu film 14 is embedded in the through hole 21 and the wiring grooves 23 by the sputtering method and a plating method. Then, the second barrier metal film 13b on the low-dielectric constant film layer 17 is removed concurrently with removal of the excessive Cu film 14 by a chemical mechanical polishing (CMP) method, thereby planarizing the device surface. In this way, for example, as shown in FIG. 7, the second Cu wirings 14b_{—1} and 14b_{—2} are formed. Of the second Cu wirings 14b_{—1} and 14b_{—2}, one second Cu wiring 14b_{—1} is formed with the contact plug which is connected to the first Cu wiring 14a being included.

At last, the second methyl radical-containing silicon nitride film 15b is likewise deposited on the low-dielectric constant film layer 17 including the second barrier metal film 13b and the second Cu wirings 14b_{—1} and 14b_{—2}. As a result, the semiconductor device having the multilayer wiring structure with the double layered device wiring shown in FIG. 1 is brought to completion.

FIG. 8 shows a relationship between the FT-IR peak height ratio and the interface adhesion strength of the buffer layer and the low-dielectric constant film layer. As apparent from FIG. 4, the interface adhesion strength K_{IC} (MPa·\sqrt{m}) depends on the FT-IR peak height ratio (%). That is, the interface adhesion strength K_{IC} of the buffer layer is improved as the FT-IR peak height ratio becomes small. Therefore, like this embodiment, by using, e.g., the buffer layer 16 whose FT-IR peak height ratio is not more than 22%, the interface adhesion strength K_{IC} relative to the first methyl radical-containing silicon nitride film 15a can be improved to 0.37 (MPa·\sqrt{m}) or more (the interface adhesion strength K_{IC} of the low-dielectric constant film layer 17 whose FT-IR peak height ratio is assumed to be not less than 25% when using no buffer layer 16 is approximately 0.33 MPa·\sqrt{m}).

A description will now be given as to a method for determining the FT-IR peak height ratio of the buffer layer 16 and the low-dielectric constant film layer 17. First, an infrared absorption spectrum of each film (layer) deposited on the Si wafer 1 is acquired by using a (Fourier Transform Infrared Spectrometer (FT-IR spectrometer)). Then, there are measured a peak height (value a) including the silicon-carbon/silicon-oxygen bond which exists in a range in the vicinity of 1245 cm⁻¹ to 950 cm⁻¹ and a peak height (value b) consisting of a silicon-methyl radical bond which exists in a range in the vicinity of 1330 cm⁻¹ to 1245 cm⁻¹. Furthermore, a value (%) obtained by (value b/value a)×100 is determined as the FT-IR peak height ratio.

A method for determining the interface adhesion (interface adhesion strength K_{IC}) of the first methyl radical-containing silicon nitride film 15a, the buffer layer 16 and the low-dielectric constant film layer 17 will now be described. First, the methyl radical-containing silicon nitride film is deposited on the Si wafer, then the buffer layer is deposited thereon, thus a sample having the low-dielectric constant film layer deposited thereon is obtained. Moreover, the interface adhesion intensity KIC of this sample is measured by an m-ELT (modified-Edge Lift off Test) method.

As described above, it is possible to suppress the mechanical strength or the interface adhesion of the low-dielectric constant film layer from being lowered. As a result, a capacitance between the wirings can be reduced without causing film cracks or film peeling. Additionally, a delay in signal transmission can be greatly improved by using Cu having a specific resistance of approximately 1/2 of that of aluminium (Al) for the device wirings.

Incidentally, in the above-described embodiment, a description has been given as to the case that the buffer layer 16 is provided only between the first methyl radical-containing silicon nitride film 15a and the low-dielectric constant film layer 17. The present invention is not restricted thereto, and the buffer layer 16 can be also provided between, e.g., the low-dielectric constant film layer 17 and the second methyl radical-containing silicon nitride film 15b. In this case, the mechanical strength or the interface adhesion of the interlevel insulating film having a low dielectric constant can be improved, and the thermal stability and the resistance characteristics with respect to the mechanical stress of the semiconductor device can be readily assured.

Additionally, in this embodiment, a description has been given as to the case that the first and second methyl radical-containing silicon nitride films 15a and 15b are used as the anti-metal diffusion films. For example, a methyl radical-containing silicon carbide film with a lower dielectric constant or a laminated film consisting of a methyl radical-containing silicon nitride film and the a methyl radical-containing silicon carbide film may be used in place of the methyl radical-containing silicon nitride film.

Further, in this embodiment, a description has been given as to the case that the double layered Cu wiring is provided. The present invention is not restricted thereto, and it can be likewise applied to the semiconductor device having the multilayered wiring structure in which the device wirings are provided in the form of two or more layers.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general invention concept as defined by the appended claims and their equivalents.

1. A semiconductor device comprising:
a metal wiring provided on a semiconductor substrate;
an anti-metal diffusion film formed on the metal wiring;
a buffer layer which is formed on the anti-metal diffusion film and includes at least a silicon-methyl radical bond and a silicon-oxygen bond; and
a low-dielectric constant film layer which is formed on the buffer layer and includes at least the silicon-methyl radical bond and the silicon-oxygen bond,
wherein the silicon-methyl radical bonding density of the buffer layer is less than the silicon-methyl radical bonding density of the low-dielectric constant film layer.

2. A semiconductor device according to claim 1, wherein a film thickness of the buffer layer is not more than 30 nm.

3. A semiconductor device according to claim 1, wherein a specific dielectric constant of the low-dielectric constant film layer is not more than 3.1.

4. A semiconductor device according to claim 1, wherein a silicon-methyl radical bonding density relative to a silicon-oxygen bond in the buffer layer is not less than 22%.

5. A semiconductor device according to claim 1, wherein a silicon-methyl radical bonding density relative to a silicon-oxygen bond in the low-dielectric constant film layer is not less than 25%.

6. A semiconductor device according to claim 1, wherein the metal wiring is a copper wiring, and the copper wiring is embedded in a surface portion of an insulating film layer provided on the semiconductor substrate having an element devices formed thereto.

7. A semiconductor device according to claim 1, wherein the anti-metal diffusion film is a methyl radical-containing silicon nitride film.

8. A semiconductor device according to claim 1, wherein the anti-metal diffusion film is a methyl radical-containing silicon carbide film.

9. A semiconductor device according to claim 1, wherein the anti-metal diffusion film is a laminated film of a methyl radical-containing silicon nitride film and a methyl radical-containing silicon carbide film.

10. A semiconductor device according to claim 1, wherein the buffer layer is a first methyl radical-containing silicon oxide film formed by using an organic silicon compound containing a methyl radical as a raw material.

11. A semiconductor device according to claim 1, wherein the low-dielectric constant film layer is a second methyl radical-containing silicon oxide film formed by using an organic silicon compound containing a methyl radical as a raw material.

12. A semiconductor device according to claim 1, further comprising an upper metal wiring layer which is connected to the metal wiring through the low-dielectric constant film layer, the buffer layer and the anti-metal diffusion film.

13. A manufacturing method of a semiconductor device comprising:
forming an anti-metal diffusion film on a metal wiring provided on a semiconductor substrate; and
forming a buffer layer including at least a silicon-methyl radical bond and a silicon-oxygen bond on the anti-metal diffusion film and forming a low-dielectric constant film layer including at least the silicon-methyl radical bond and the silicon-oxygen bond on the buffer layer,
wherein the buffer layer is formed in such a manner that its silicon-methyl radical bonding density is less than the silicon-methyl radical bonding density of the low-dielectric constant film layer.

14. A method according to claim 13, wherein a film thickness of the buffer layer is controlled to be not more than 30 nm.

15. A method according to claim 13, wherein a specific dielectric constant of the low-dielectric constant film layer is controlled to be not more than 3.1.

16. A method according to claim 13, wherein the buffer layer is film-formed in such a manner that a silicon-methyl radical bonding density relative of a silicon-oxygen bond is not more than 22%.

17. A method according to claim 13, wherein the buffer layer is formed under a pressure being controlled to be not more than 3 torr during the film formation.

18. A method according to claim 13, wherein the buffer layer is formed by an RF (Radio Frequency) power density being controlled to be not less than 2 W/cm³.

19. A method according to claim 13, wherein a flow rate ratio of the methyl radical-containing organic silicon compound and oxygen is controlled to be 1:5 during the buffer layer formation.

20. A method according to claim 13, wherein the low-dielectric constant film layer is formed in such a manner that a silicon-methyl radical bonding density relative to a silicon-oxygen bond is not less than 25%.

21. A method according to claim 13, wherein the metal wiring is a copper wiring, and the copper wiring is embedded in a surface portion of an insulating film layer provided on the semiconductor substrate having element devices formed thereto.

22. A method according to claim 13, wherein a methyl radical-containing silicon nitride film is used for the anti-metal diffusion film.

23. A method according to claim 13, wherein a methyl radical-containing silicon carbide film is used for the anti-metal diffusion film.

24. A method according to claim 13, a laminated film of a methyl radical-containing silicon nitride film and a methyl radical-containing silicon carbide film is used for the anti-metal diffusion film.

25. A method according to claim 13, wherein the buffer layer and the low-dielectric constant film layer are formed by using an organic silicon compound containing a methyl radical as a raw material.

26. A method according to claim 25, wherein the buffer layer and the low-dielectric constant film layer are continuously formed without turning off a power supply.

27. A method according to claim 13, wherein the buffer layer and the low-dielectric constant film layer are discontinuously formed by turning on a power supply again.
